(19) United States
(12) Patent Application Publication
(10) Pub. No.: US 2007/0039645 A1
(43) Pub. Date: Feb. 22, 2007

(54) Photovoltaic element

(76) Inventor: Wolf Nagel, Koln (DE)

Correspondence Address: NEEDLE & ROSENBERG, P.C., SUITE 1000, 999 PEACHTREE STREET, ATLANTA, GA, 30309-3915, US

(21) Appl. No.: 10/573,864

(22) PCT Filed: Sep. 30, 2004
(86) PCT No.: PCT/EP04/10916

§ 371 Date: May 5, 2006

(30) Foreign Application Priority Data
Oct. 1, 2003 (DE) 103 45 736.4

(51) Int. Cl. H01L 31/00

(52) U.S. Cl. 136/261

(57) ABSTRACT

A photovoltaic element, in particular, for application as solar cell for photovoltaic units, comprises a photon absorber. An electrically conductive working element is at least partly embedded in the photon absorber. The working element is separated from the photon absorber by means of a phase boundary. The working element further comprises a higher electron mobility than the photon absorber. It was surprisingly discovered that the efficacy of said photovoltaic element is greatly increased.

The invention refers to a photovoltaic element used in particular in photovoltaic installations as a solar cell for generating electric energy by absorbing sunlight.

Highly efficient solar cells are known for example from “Sonnenenergie: Photovoltaik” (B. G. Teubner Verlag, Stuttgart, 1997) or “Forschungsverbund Sonnenenergie Themen 95/96, Photovoltaik 3”. According thereto, highly efficient photovoltaic elements comprise a photon absorber referred to as a “p-base” made of monocrystalline, zone-melted and p-doped (approx. 1.5×10¹⁶ cm⁻³) silicon. The photon absorber has an electric conductivity of approx. 1 Ω⁻¹cm⁻¹) and a thickness of about 200 μm. The front side of the photon absorber is textured with recessed inverted pyramids. To obtain a high anti-reflection effect, the front side of the photon absorber is covered by a thermally grown silicon dioxide layer approx. 100 nm in thickness. Beneath the SiO₂ layer, an emitter layer is provided having a doting of approx. 1×10¹⁹ cm⁻³-1×10²⁰ cm⁻³ and a penetration depth of about 0.5-3 μm. To supply or dissipate the electrons excited by the absorption of light quants, the front side of the photon absorber exposed to the light is provided with metal conductors made of Ti—Pd—Ag. Aluminum is vapor deposited on the bottom side of the photon absorber as a rear contact. The vapor deposited aluminum is connected to a back surface field (BSF) through point contacts. The point contacts and the BSF ensure electric contact between the vapor deposited aluminum and the photon absorber.

Using such photovoltaic elements, a peak efficiency of 21.3% can be achieved. However, this efficiency is still too low. Especially for obtaining a large-scale switch from fossil fuels to renewable energy sources, in particular with the help of photovoltaics, the present achievable efficiencies of photovoltaic elements are insufficient.

From DE 198 37 365 A1 it is known to provide clusters of gold, silver or gallium arsenide in the optical area of a solar cell that is exposed to sunlight. The cluster size is between 3000 and 10000 atoms and they are smaller than 10 μm. By a resonance effect, the clusters create additional pairs of charge carriers that provide additional electric current, thereby improving the efficiency. It is a drawback of such a solar cell that the materials used for the clusters are rather expensive. Moreover, it is complicated and troublesome to introduce the clusters into the material used for the photon absorber, the clusters being very small compared to the solar cell.

It is an object of the present invention to provide a photovoltaic element or a photovoltaic device that is easy to manufacture and has an improved efficiency.

The object is solved according to the invention by a photovoltaic element with the features of claim 1 and by a photovoltaic device with the features of claim 16.

Surprisingly, it has been found that a higher efficiency can be obtained with a photovoltaic element of the present invention in which an electrically conductive working element is at least partly embedded in a photon absorber. The photon absorber, which may be the absorber layer of a conventional solar cell, for example, is especially p-doped and thus designed as a “p-base”. Here, the working element is separated from the photon absorber by a phase boundary, i.e. the working element is not a doping of the photon absorber or an alloy of the photon absorber, but an element having different physical characteristics than the photon absorber. Moreover, the working element has a higher electron mobility than the photon absorber. In particular, the electric conductivity of the working element is higher than that of the photon absorber. Preferably, the electric conductivity of the working element is higher than 1.4 Ω⁻¹cm⁻¹, more preferred higher than 1.6 Ω⁻¹cm⁻¹, especially higher than 2.0 Ω⁻¹cm⁻¹ and, in particular, even higher than 8.0 Ω⁻¹cm⁻¹. According to the invention, the working element is made as a large surface element and has a large surface as compared to the volume. To this end, the working element is elongate in particular, for example an elongate cylinder or parallelepiped. The ratio of the surface to the volume is especially greater than 2.5, preferably greater than 4.0, and particularly preferred more than 6.5.

The volume ratio of the photon absorber to the conductors preferably is in the range between 2-7. Particularly preferred is a volume ratio of about 4.

The working element may be a conductor, for example, such that, compared to conventional photovoltaic elements, the conductor is not arranged outside but inside the photon absorber. Surprisingly, it has been found that a preferred embodiment of the working element is electrically insulated, i.e. the working element is connected neither to a positive nor a negative pole, but is arranged at least partly within the photon absorber. Thus, the working element can be a conductor that is neither connected to a positive nor a negative pole, but is embedded in the photon absorber without contact to a voltage source.

It seems that the embedded part of the working element has a certain amplifying property. The electrons excited by light quants seem to easily transfer their electric impulse to the electrons within the working element. This electric impulse is reflected within the working element at the phase boundaries with the media having a higher ohmic resistance, namely in particular the photon absorber or the environment, until sufficient energy is stored in the working element to be able to transmit a high-energy electric impulse from the working element through the photon absorber to an electric conductor. The conductors need not be a part of the present photovoltaic element, but they can also be an outer abutment surface of a photovoltaic device receiving the photovoltaic element, for example. It is assumed that the effect is due to a resonance phenomenon causing an amplifying effect. Thus, the working element is an amplifying element or an electric resonant body. The working element thus causes electric resonance with a wave characteristic having a frequency bandwidth of approx. 75 Hz-85 Hz. The working element may especially store the electrons and emit them to the photon absorber depending on temperature, for example, whereby additional electron/hole events are triggered that result in an additional amplifying, thereby improving the efficiency.

The absorption of photons in the photon absorber creates electron/hole pairs which can be drained from the photon absorber through an electric field as electric current. To this avail, for example, opposite sides of the photon absorber may be provided with capacitor plates connected to a positive pole or a negative pole, respectively. In a preferred embodiment an electric field is created by providing at least one conductor that is at least partly embedded in the photon absorber. This avoids capacitor plates arranged outside the photon absorber. Similar to the working element, the conductor may be embedded in the photon absorber, thereby avoiding different production processes and reducing manufacturing costs. Further, the conductor may have the same composition as the working element so that providing different material compositions is avoided. Thus, it is possible to first produce a large-surface photon absorber into which a plurality of working elements is embedded. Thereafter, the large-surface photon absorber can be divided into several small photon absorbers. To create the electric field, individual working elements can be designed as conductors. For example, a cable connected to a positive or a negative pole may be soldered to one of the working elements. Preferably, individual working elements are connected in series. Thus, a fully functional solar cell can be made by structurally simple measures suited for mass production.

In a preferred embodiment, at least two conductors are arranged in the photon absorber, one of the conductors being a positive conductor connected to a positive pole, while the other conductor is a negative conductor connected to a negative pole. In a particularly preferred embodiment, the positive conductors are arranged such that they end at or protrude beyond a first front end side of the photon absorber, and the negative conductors, in a corresponding design, end at or protrude beyond a second front side of the photon absorber. Thus, in a very simple manner, it is possible to interconnect a plurality, especially all, positive conductors through a first omnibus conductor at the first front side, and to interconnect a plurality, especially all, negative conductors through a second omnibus conductor at the second front side.

Preferably, the photovoltaic element is of a multilayered structure. In this embodiment, the photovoltaic element comprises at least two photon absorbers which are in contact through an abutment surface. Preferably, the orientation of the photon absorbers is anti-parallel. In a particularly preferred embodiment, the positive conductors and the negative conductors are arranged such that the positive conductors and the negative conductors are separated by the abutment surface. Thereby, a greater spatial separation of the positive conductors and the negative conductors is achieved. Further, both photon absorbers, in which, for example, both working elements and conductors are arranged, can be of identical structure with the conductors of the photon absorber being connected to the positive pole and the conductors of the other photon absorber being connected to the negative pole. Thereby, the present photovoltaic element is particularly suited for mass production. Preferably, the photovoltaic element may, e.g., comprise four layers, the third and fourth layers respectively being anti-parallel to the first and second layers, for example. This allows to increase the degree of absorption. For a further increase in the degree of absorption, more than four layers may be provided.

Preferably, the photon absorber is substantially made of silicon, in particular monocrystalline silicon, which is possibly doped so that a “p-base” is created.

For a larger part, especially completely, the working element is preferably made of metal and is possibly doped or alloyed. For reasons of high raw material costs, the metals Pt, Ag and Au are preferably avoided. In particular, the metal is from the 3.-6. main group or the 1. to 8. subgroup of the periodic table of elements. Preferably, the metal is a subgroup metal whose electron configuration has an outer d-shell occupied by at least ten electrons.

The invention further refers to a photovoltaic device comprising a receiving element with recesses. These recesses accommodate above described photovoltaic elements. The photovoltaic device comprises a first and a second connecting conductor connected to a positive pole or a negative pole. The connecting conductor ensures the electric connection to the photovoltaic elements. To this avail, the connecting conductors are connected in particular to the positive conductor or the negative conductor and/or, if present, to the corresponding omnibus conductor. Thereby, it is possible to connect, in a cost-saving and modular structure, a plurality of photovoltaic elements which themselves are possibly assembled modularly. For this purpose, a recess is provided with a plurality of photovoltaic elements, the recess being in contact with at least one photon absorber of the photovoltaic element and is insulated from the conductors, in particular. In a preferred embodiment, the photovoltaic device is electrically conductive at least in the region of the recesses and is composed of a preferably aluminum-containing metal, such as AIP, which is possibly doped. The receiving element substantially has an amplifying function that can be explained as follows: all electrons from the photon absorber with an energy of at least 0.8 eV, which either result from the p-base by photoinduction or, additionally, come from the working element due to resonance induction, reach the receiving element under given geometric conditions, where they trigger electric motions that cause an amplifying effect so that the outflowing electrons return into the photon absorber in approximately in triple numbers. This electron portion flowing back into the photon absorber from the receiving element is increased by photo-induced electrons of such quantities of residual light that impinge on the receiving element. In this respect, especially the photovoltaic elements are configured to fit into the recess of the receiving element, so that preferably a direct contact between the receiving element and the photovoltaic element is obtained.

Preferably, a plurality of first connecting conductors are connected to exactly one first current conductor and a plurality of second connecting conductors are connected to exactly one second current conductor. Thus, the entire voltage provided by means of the photovoltaic device can be tapped using a single pair of conductors. The second current conductor fulfills the function of the “back surface field”, the “back surface field” being reduced to a “back surface line”. Thus, it is possible to spatially separate the thus formed “back surface line” to avoid electric short currents or to reduce interfering electric fields. The material usage for forming the rear contact is thereby reduced.

In contrast to known systems, the invention provides that the electric field necessary for separating the charges is spread over a wide space and covers the following components of the photovoltaic element in particular:
the ribbon-shaped/wire-shaped conductor corresponds in function to the n⁺ emitter,
the negative plate is embedded in a silicon matrix,
the silicon layers are designed as pairs, each with an anti-parallel orientation,
the positive plate is embedded in a silicon matrix.

In a particularly preferred embodiment, the photovoltaic device comprises connecting means to mechanically and electrically connect at least two photovoltaic devices arranged side-by-side. The mechanic or electric connection may be achieved both with different and with a common connecting means. Thus, it is possible to modularly connect a plurality of photovoltaic devices and to possibly connect them in series, for example to thereby assemble a particularly large photovoltaic installation.

An independent invention provides for a method for producing monocrystalline anisotropic silicon. First, a parallelepiped of doped monocrystalline silicon is cut in slices corresponding to the intended layer thickness of a photon absorber for a photovoltaic element. This slice is slowly, e.g. within 90 minutes, heated to its melting point and, in particular, maintained at this temperature level for approx. 30 minutes. Thereafter, the silicon slice is cautiously cooled to approx. 300° C., especially in intervals, for eight hours, for example. From approx. 300° C., the cooling can be done without control. After this procedure, a preferably circular slice of monocrystalline anisotropic silicon having uniform layer thickness is obtained. Preferably, three photon absorbers are cut or sawed from the silicon slice, which are arranged under a defined angle with respect to each other, especially radial symmetrically. With this method, photon absorbers can be produced that have a highly homogeneous orientation of the crystal structure. Thus, it is possible to arrange two photon absorbers in an anti-parallel orientation with respect to each other, whereby the capability of absorbing light quants is enhanced. Thus, the mutually anti-parallel anisotropic photon absorbers have mutually oppositely directed orientations of the crystal structure (α=180°).

The following is a detailed description of preferred embodiments of the invention with reference to the accompanying drawings.

In the Figures

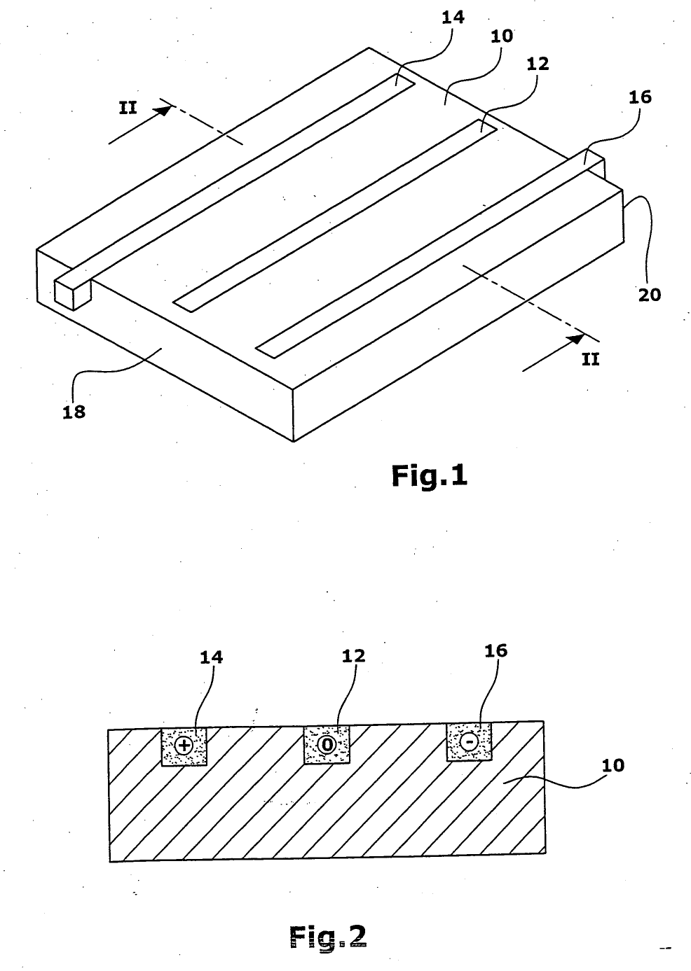

FIG. 1 is a schematic perspective view of a photovoltaic element,

FIG. 2 is a schematic section through the photovoltaic element along line II-II of FIG. 1,

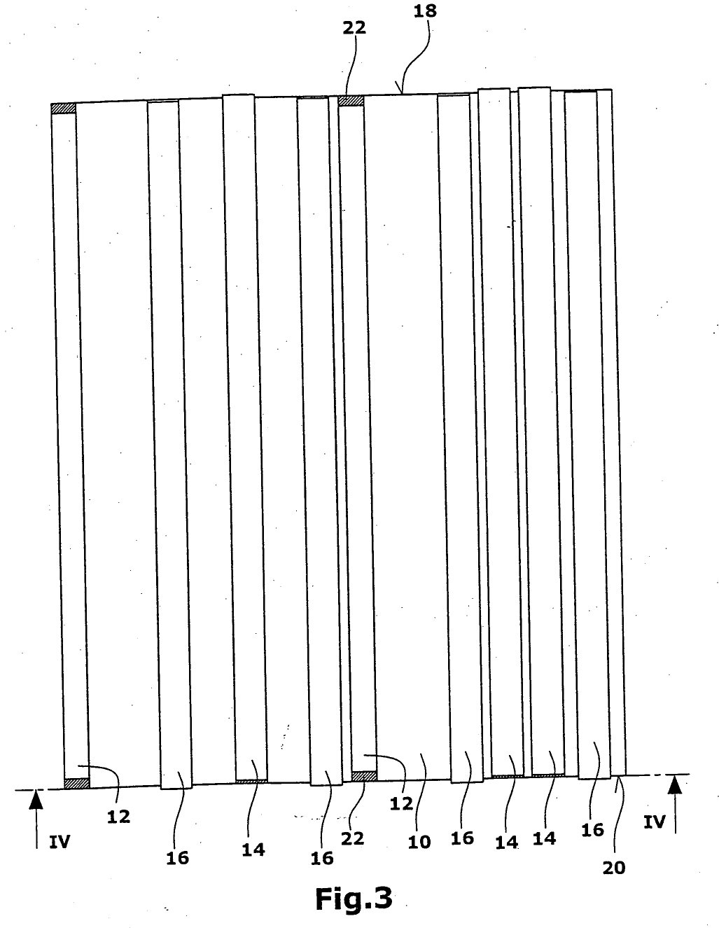

FIG. 3 is a schematic top plan view of a second embodiment of the photovoltaic element,

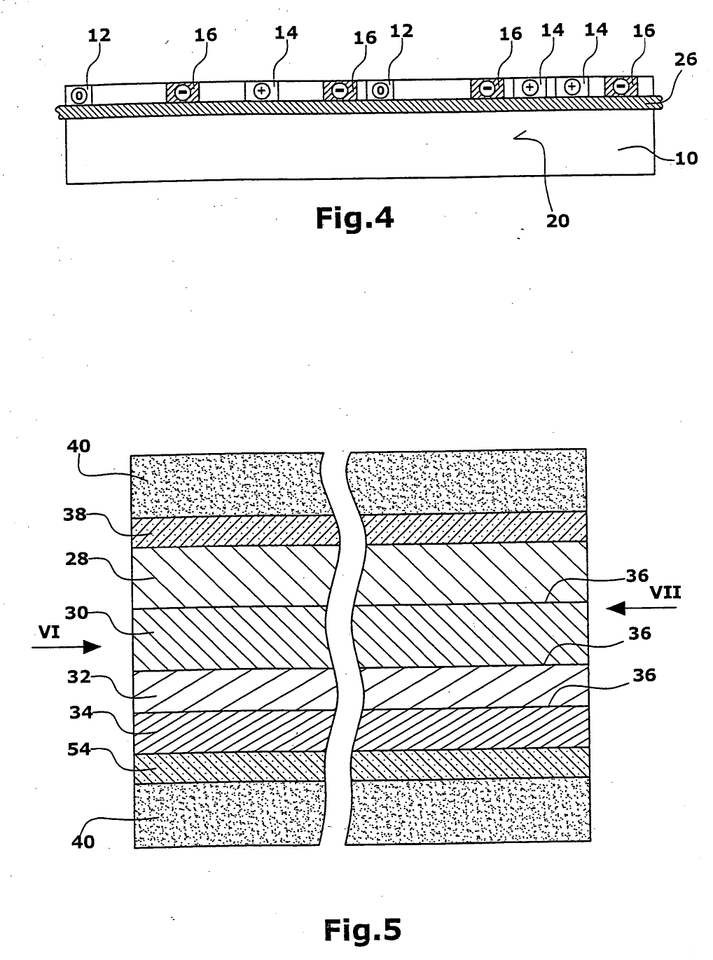

FIG. 4 shows a schematic sectional side view of the photovoltaic element along line IV-IV of FIG. 3,

FIG. 5 shows a schematic side view of a multi-layered photovoltaic element,

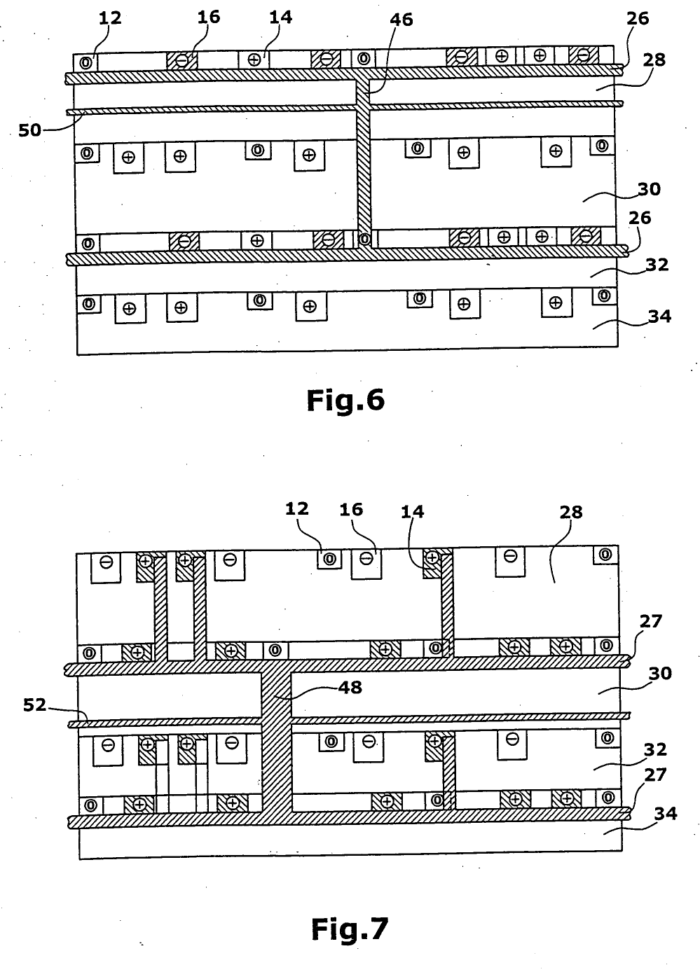

FIG. 6 shows a schematic sectional side view of the photovoltaic element in the direction of the arrow VI in FIG. 5,

FIG. 7 shows a schematic sectional side view of the photovoltaic element in the direction of the arrow VII in FIG. 5,

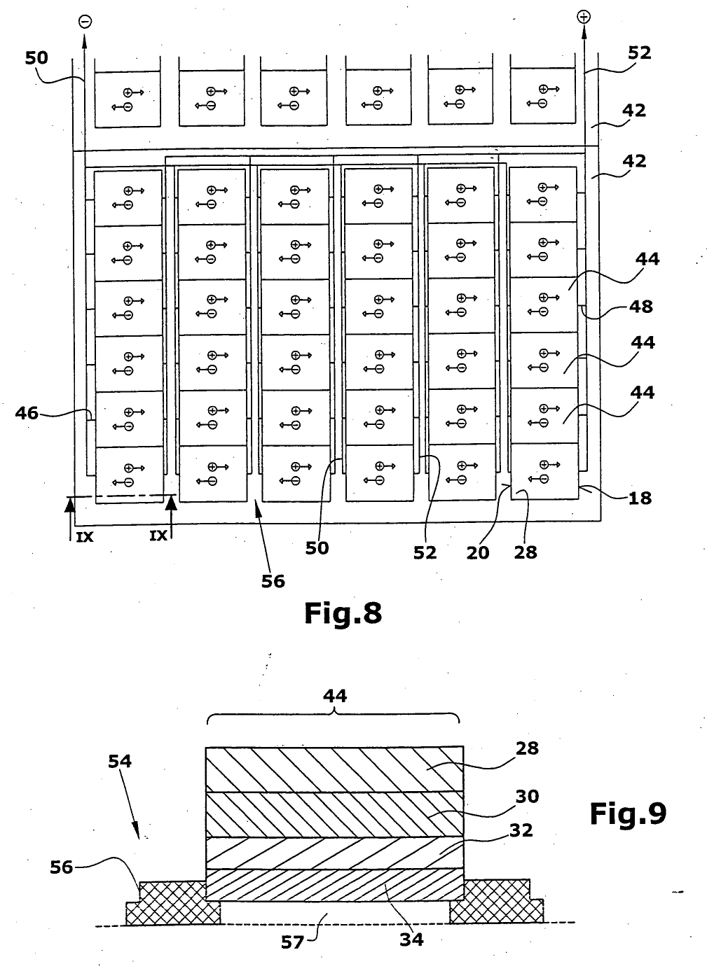

FIG. 8 is a schematic top plan view of a photovoltaic device,

FIG. 9 shows a schematic sectional side view of the photovoltaic device along the line IX-IX in FIG. 8, and

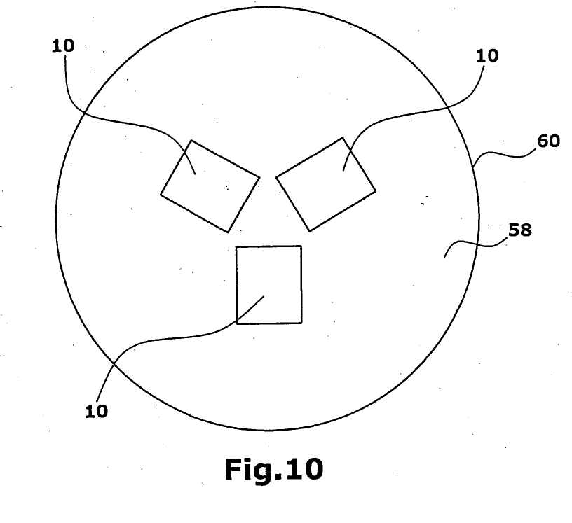

FIG. 10 is a schematic top plan view of a silicon slice for making photon absorbers.

In a photon absorber 10, illustrated in FIG. 1, an electrically conductive working element 12 is embedded electrically insulated. Further working elements are designed as a positive conductor 14 and a negative conductor 16. For easy soldering, a part of the positive conductor 14 protrudes beyond a first front side 18 of the photon absorber 10. Similarly, a part of the negative conductor 16 projects beyond a second front side 20 of the photon absorber 10.

The photon absorber 10 can absorb electromagnetic radiation especially in the range between 95 nm and 1220 nm. The absorption maxima of the photon absorber 10 are at 130 nm±15 nm and 720 nm±15 nm, in particular. Thus, a degree of absorption of electromagnetic radiation of approx. 42% can be achieved.

The working element 12, the positive conductor 14 and the negative conductor 16 are entirely embedded in the photon absorber 10. Their surfaces averted from the photon absorber 10 are flush with the surface of the photon absorber 10 (FIG. 2).

In another embodiment of the present photovoltaic element, a plurality of working elements 12, positive conductors 14 and negative conductors 16 are arranged in the photon absorber 10 (FIG. 3). A mutual distance between the working elements 12, positive conductors 14 and negative conductors 16 exists at which the efficiency is particularly high. This distance can possibly be determined by experiments in dependence on the material used. For the electric insulation of the working elements 12, silicone pads 22 are arranged between the front sides 18, 20 of the photon absorber 10 and the front faces of the working elements 12. The working elements 12, the positive conductor 14 and the negative conductors 16 are elongate and arranged substantially in parallel to each other. The working elements 12, the positive conductors 14 and the negative conductors 16 are designed substantially as strips arranged side by side and having a substantially parallelepiped geometry.

The protruding ends of the positive conductors 14 and of the negative conductors 16 are connected to a first omnibus conductor 24 and a second omnibus conductor 26, respectively, especially by soldering (FIG. 4). The omnibus conductors 24, 26 are provided on the first front side 18 and on the second front side 20, respectively.

The present photovoltaic element may be single-layered, double-layered or multi-layered (FIG. 5). The photon absorber 10 may comprise four layers 28, 30, 32, 34, for example, each being in contact through abutment faces 36. To create a high anti-reflection effect and to increase the light or radiation absorption, the photon absorber 10 preferably has its top surface and its bottom surface provided with a textured polycarbonate layer 38 to act as a “light trap”. On both sides, the exterior of the polycarbonate layer 38 itself is provided with a glass layer 40 to protect the present photovoltaic element from damage. To achieve the maximum possible light absorption, the first layer 28 and the third layer 32 have a mutually anti-parallel anisotropic crystal structure. Similarly, the second layer 30 and the fourth layer 34 also have a mutually anti-parallel anisotropic crystal structure. The multi-layered photovoltaic element 44 is held by a receiving element 54. The aperture angle or the angle of incidence for electromagnetic radiation that can be absorbed by the photon absorber 10 or the layers 28, 30, 32, 34 is thus larger than 130° and up to approx. 153°.

Preferably, a gas with a low oxygen content, such as nitrogen, is filled in. Thus, the yield can be increased by 10%. Preferably, possibly in addition to the reduction of the warming effect, a vacuum of especially 0.3-0.5 bar is also created.

In the multi-layered embodiment of the present photovoltaic element, the omnibus conductors 24, 26 preferably also extend over several layers (FIG. 6, FIG. 7). Therefore, the omnibus conductors 24, 26 are arranged longitudinally, for example. Since the positive conductors 144 and the negative conductors 16 protrude from opposite front sides 18 and 20, the risk of a short circuit is avoided. However, it is preferred not to place the omnibus conductors 24, 26 over the ends of oppositely charged conductors to avoid possible interferences by strong electric fields in this area and short circuits, respectively.

A present photovoltaic device 42 comprises a plurality of the present photovoltaic elements 44 (FIG. 8). Within cells, the first omnibus conductors 26 of the photovoltaic elements 44 are each connected to a connecting conductor 46. Similarly, omnibus conductors 27 are connected to a connecting conductor 48. The latter form the rear contact configured as a “back surface line”, whereas the omnibus conductors 26 correspond in function to the n⁺-emitters of conventional photovoltaic systems. The connecting conductors 46 and 48 of the individual photovoltaic elements are further electrically connected through to the end poles. Further, the photovoltaic device 42 comprises connecting means (not illustrated) to mechanically connect adjacent photovoltaic devices 42. Further, the current conductors 50, 52 of adjacent photovoltaic devices 42 are electrically interconnected. FIGS., 6 and 7 show a possible structure of the arrangement of subsequent conductors. These are connected in series.

To receive a plurality of photovoltaic elements 44, the photovoltaic device 42 has receiving elements 54 with recesses 56 (FIG. 9). The photovoltaic elements 44 are placed into the recesses 56 of the receiving elements 54. Here, the receiving element 54 can act as an amplifier by being at least partly electrically conductive and being in contact with the third layer 32 and the fourth layer. A contact with conductors of opposite polarity should preferably be avoided. In a preferred structure, the receiving element 44 has an opening 57 beneath the lowermost layer 34, whereby material is saved. Possibly, the opening 57 can be closed entirely, e.g. with AIP. The layers 28, 30, 32, 34 are especially designed as a thick layer system with a total thickness of approx. 3 mm to 18 mm, so that the risk of a breaking of the photovoltaic element 44 is reduced.

To produce the photon absorbers 10, first a silicon slice 58 of monocrystalline anisotropic silicon is made (FIG. 10), from which the photon absorbers 10 are sawed. Preferably, the photon absorbers 10 to be sawed are located at a distance from an edge 60 of the silicon slice 58 to avoid possible structural defects in the atom grid in the edge portion of the silicon slice 58. The rest of the silicon slice 58, remaining after the photon absorbers 10 have been sawed, can afterwards be melted and reused, so that the material of the silicon slice can be fully recycled.

1. A photovoltaic element comprising
a photon absorber and
an electrically conductive large-surface working element that is at least partly embedded in the photon absorber,
the working element being separated from the photon absorber by a phase boundary, and the working element having a greater electron mobility than the photon absorber.

2. The photovoltaic element of claim 1, characterized in that the working element is substantially electrically insulated.

3. The photovoltaic element of claim 1, characterized in that at least one conductor is at least partly embedded in the photon absorber, which conductor especially has the same composition as the working element.

4. The photovoltaic element of claim 3, characterized in that the working element and the conductors are elongate and substantially parallel to each other.

5. The photovoltaic element of claim 3, characterized in that the conductors are configured as a positive conductor and a negative conductor the positive conductor ending at or protruding beyond a first front side of the photon absorber and the negative conductor ending at or protruding beyond a second front side of the photon absorber.

6. The photovoltaic element of claim 5, characterized in that, in a multi-layered structure, at least two photon absorbers are provided that are in contact via an abutment surface in which the positive conductors and the negative conductors are arranged such that the positive conductors and the negative conductors are separated from each other by the abutment surface.

7. The photovoltaic element of claim 5 characterized in that a plurality of positive conductors are connected with each other through a first omnibus conductor and a plurality of negative conductors are connected with each other via a second omnibus conductor.

8. The photovoltaic element of claim 1, characterized in that the photon absorber is substantially made of silicon, especially of anisotropic monocrystalline silicon.

9. The photovoltaic element of claim 8, characterized in that two respective photon absorbers have a mutually anti-parallel crystal structure.

10. The photovoltaic element of claim 1, characterized in that the working element is made mostly, especially entirely, of metal.

11. The photovoltaic element of claim 10, characterized in that the metal of the working element is from the 3.-6. main group or is a subgroup metal from the 1.-8. subgroup, its electron configuration preferably having a d-layer occupied by at least ten electrons.

12. The photovoltaic element of claim 1, characterized in that the working element has an electric conductivity higher than 1.4 Ω⁻¹cm⁻¹, preferably higher than 1.6 Ω⁻¹cm⁻¹, more preferred higher than 2.0 Ω⁻¹cm⁻¹.

13. A photovoltaic device comprising a receiving element (54) with recesses in which at least one photovoltaic element of claim 1 is arranged, wherein conductors present in the photovoltaic element are each connected to omnibus conductors.

14. The photovoltaic device of claim 13, characterized in that a plurality of photovoltaic elements are arranged in at least one recess, the recess being in contact with at least one photon absorber of the photovoltaic element.

15. The photovoltaic device of claim 13, characterized in that a plurality of first connecting conductors and a plurality of second connecting conductors are each connected with first current conductors and second current conductors respectively.

16. The photovoltaic device of claim 13, characterized by connecting means for mechanically and electrically connecting at least two photovoltaic devices arranged side by side.
